(19) United States
(12) Patent Application Publication
(10) Pub. No.: US 2005/0170627 A1
(43) Pub. Date: Aug. 4, 2005

(54) Interconnect apparatus, system, and method

(76) Inventors: Thomas Mowry, Cardiff, CA (US); Cuong V. Pham, San Diego, CA (US)

Correspondence Address: KIRKPATRICK & LOCKHART NICHOLSON GRAHAM LLP, 535 SMITHFIELD STREET, PITTSBURGH, PA, 15222, US

(21) Appl. No.: 10/768,250

(22) Filed: Jan. 30, 2004

(51) Int. Cl. H01L 21/44

(52) U.S. Cl. 438/612

(57) ABSTRACT

An apparatus, system, and method for forming a connector including a frame, a conductor, and a solder ball formed on a conductive land of the conductor. The method includes depositing solder mask on a conductive pad of a conductor, depositing solder paste in the area defined by the solder mask, and forming a solder ball by reflowing the solder paste. The system includes a first component including a first contact pad, a second component including a second contact pad thereon, and a connector that includes a frame, a conductor including electrically continuous first and second portions, the first portion extending outwardly from the first side of the frame and terminating in a tip in electrical communication with the first contact pad, the second portion extending through the second side of the frame and terminating in a land in electrical communication with the second contact pad, and a solder ball formed on the land.

### BACKGROUND

The present invention relates generally and in various embodiments to electrical interconnect devices for electrically connecting the contacts of a first component to the contacts of a second component. More specifically, the present invention is directed in various embodiments to high density miniature electrical interconnect devices having an array of closely spaced conductors and solder balls suitable for temporary or permanent solder connection to substrates such as circuit boards and the like.

Generally, solder joints or interconnect devices are used to connect semiconductor components to a substrate. Today's growing and technologically demanding semiconductor manufacturing assembly processes require high-density interconnect devices for connecting the semiconductor components to the substrates. High-density surface mount semiconductor socket connectors having over 1,000 high-density contacts often are used as interconnect devices to accommodate the increased complexity and functionality of modern semiconductor components.

Modern equipment often requires electrical interconnect devices that are capable of simultaneously connecting large numbers of electrical circuits from one electronic component to another. Generally, in such applications, the electrical interconnect devices include a frame having opposed contact surfaces. Each contact surface, for example, is provided for engaging corresponding contact surfaces on other electronic components. The interconnect frame functions to hold the midsections of a plurality of individual electrical conductors, and also to electrically isolate each conductor from the remaining conductors. In addition, the frame generally incorporates features for mechanically attaching the electronic components to one another. Conventional interconnect devices have conductors that are molded-in-place within the frame. In these connectors, each conductor has a first element that projects from a first side of the frame and a second element that projects from a second, opposed, side of the frame. The midsection of each conductor provides a connection from the first element to the second element.

In modern equipment, electronic components have become increasingly miniaturized, while the number of circuits in each electronic component has multiplied. These effects have combined to require smaller connectors having increasingly smaller spacings between adjacent conductors. Unfortunately, for mold-in-place connectors, small spacings between adjacent conductors are not readily obtainable when the conductor midsections are oriented parallel to the contact surfaces of the frame.

Interconnect devices have been specially adapted to operate in conjunction with ball grid array (BGA) type devices. The BGA package is used with integrated circuits having very high pin counts. The BGA package replaces the conventional pins with a solder “ball” structure comprised of reflowed (melted) and solidified small beads of solder paste. The BGA package saves space on the substrate. Certain BGA type interconnect devices may include, for example, contacts having first and second portions, where the first portion may be soldered directly to a printed circuit board type substrate while the second portion is provided in electrical contact with soldered balls formed on the semiconductor package. The solder balls then are compressed onto the second contacts portion of the interconnect device and reflowed during the assembly process. These types of interconnect devices work well with conventional BGA packages. In use, the semiconductor package is compressed onto the contacts portion with a predetermined force for a predetermined period. The first portion of the contacts is generally soldered directly to a printed circuit board type substrate, for example. This process, however, may lead to stress in the solder joints and thus may have limited value in high volume production parts.

Furthermore, conventional surface mountable land grid array (LGA) interconnect devices experience several common issues such as relaxation of the metal used as the electrical contacts, which causes open circuits specifically on the substrate side. Other issues include difficulties in placing the LGA interconnect device in coplanar relation with the substrate and the warping of the substrate relative to the interconnect device whenever these components are not aligned in a coplanar manner. Also, conventional interconnect devices rely on mechanical contacts rather than solder joints to provide the electrical interconnection. Also, conventional surface mountable LGA interconnect devices cannot be temporarily soldered and easily removed or permanently soldered to the substrate. In addition, it is difficult to control the solder ball height formed on the semiconductor component due to the uncontrolled wetting surface of the contacts. Other problems with conventional interconnect devices include metal contacts that experience uneven torque during assembly and metal contacts loosening after insert molding into the frame.

### SUMMARY

In one general respect, an embodiment of the present invention is directed to a connector that includes a frame having a first side and a second side; a conductor including electrically continuous first and second portions, the first portion extending outwardly from the first side of the frame and terminating in a tip, the second portion extending through the second side of the frame and terminating in a land; and a solder ball formed on the land.

In another general respect, an embodiment of the present invention is directed to a method of forming a connector including a solder ball. The method includes depositing solder mask on a conductive pad of a conductor, the solder mask defining an area for receiving solder paste; depositing solder paste in the area defined by the solder mask; and forming a solder ball by reflowing the solder paste.

In yet another general respect, an embodiment of the present invention is directed to a method of forming a connector including a solder ball. The method includes depositing a first solder paste on a first substrate comprising a convex region; introducing a conductive pad of a conductor in communication with the first solder paste; reflowing the first solder paste to form a first solder ball defining a reservoir; depositing a second solder paste of lower melting temperature on a second substrate; introducing the reservoir portion of the first solder ball in communication with the second solder paste; and reflowing the second solder paste to form a second solder ball within the reservoir of the first solder ball.

In still another general respect, an embodiment of the present invention is directed to an interconnect system. The system includes a first component including a first contact pad thereon; a second component including a second contact pad thereon; and a connector. The connector includes a frame having a first side and a second side; a conductor including electrically continuous first and second portions, the first portion extending outwardly from the first side of the frame and terminating in a tip in electrical communication with the first contact pad, the second portion extending through the second side of the frame and terminating in a land in electrical communication with the second contact pad; and a solder ball attached on the land.

Other apparatuses, systems, and/or methods according to embodiments of the present invention will be or become apparent to one with skill in the art upon examination of the following drawings and detailed description. It is intended that all such additional apparatuses, systems, and/or methods be included within this description, be within the scope of the present invention, and be protected by the accompanying claims.

### DESCRIPTION OF THE DRAWINGS

Embodiments of the present invention are described herein in conjunction with the following figures, wherein:

FIG. 1 is a perspective view of an electrical connector shown together with two electronic components according to one embodiment of the present invention; and

FIG. 2 is a side perspective view of a portion of an electrical connector according to one embodiment of the present invention;

FIG. 3 illustrates one embodiment of an electrical connector that includes a plurality of electrical conductors molded in place within a frame;

FIG. 4 illustrates another embodiment of an electrical connector that includes a plurality of electrical conductors molded in place within a frame;

FIGS. 5A-E illustrate a process sequence according to one embodiment of the present invention for forming solder balls on an electrical connector according to one embodiment of the present invention;

FIGS. 6A-H illustrate a process sequence according to the present invention for forming dual solder balls on a connector according to the present invention; and

FIG. 7 illustrates one embodiment of an electrical conductor comprising anti-pivot elements in accordance with the present invention.

### DESCRIPTION

It is to be understood that the figures and descriptions of the various embodiments of the present invention described herein, among others, have been simplified to illustrate representative elements of apparatuses, systems, and methods for electrically connecting a first component to a second component while eliminating, for purposes of clarity, other elements. Those of ordinary skill in the art will appreciate and readily understand, however, that other elements that may be found in conventional communications interconnect devices may be included in the various embodiments of the present invention.

As used herein, the term “first component” may comprise a semiconductor component which may include, for example, microprocessors, application specific integrated circuit (ASIC) devices, programmable logic array devices, packaged semiconductor devices, semiconductor multichip modules, semiconductor chip set arrays, other digital, analog, and/or mixed signal integrated circuit components, etc. Furthermore, the term “second component” may comprise a substrate which may include, for example, printed circuit boards, ceramic boards, flexible circuits, other substrates suitable for permanently or temporarily attaching semiconductor components and interconnect devices thereto, etc.

One embodiment of the present invention provides an interconnect device such as a molded electrical connector suitable for temporary or permanent connection to a substrate through electrical connections such as solder joints, for example. In one embodiment of the present invention the electrical connector is a surface mountable LGA socket suitable for temporary or permanent connection to the substrate. One embodiment of the LGA socket according to the present invention is formed to receive an LGA type semiconductor integrated circuit (IC) package therein.

Further, one embodiment of the LGA socket according to the present invention includes a plurality of resilient metal contacts formed on a lead frame, which are embedded within a body portion of a frame. On one side of the interconnect device, the resilient contacts provide an electrical connection to a first component such as a semiconductor IC package inserted therein. On another, opposed side of the interconnect device, the resilient contacts provide an electrical connection to a second component such as a substrate. Various embodiments of the present invention include resilient contacts comprising a layer of solder mask on the lead frame, anti-pivot elements, and primary and secondary spring force features.

Referring now to the several drawings in which identical elements are numbered identically throughout, a description of the present invention will now be provided, in which exemplary embodiments are shown in the several figures. The present invention, however, may be embodied in many different forms and should not be construed as being limited to the embodiments set forth herein. Rather, these embodiments are provided so that this disclosure will be thorough and complete, and will fully convey the scope of the invention to those having ordinary skill in the art. Furthermore, all statements herein reciting embodiments of the invention, as well as specific examples thereof, are intended to encompass both structural and functional equivalents thereof. Moreover, it is intended that such equivalents include both currently-known equivalents as well as equivalents developed in the future for performing the same function, regardless of structure. Thus, those skilled in the art will appreciate that the schematic drawings presented herein, and the like, represent conceptual views of illustrative structures which may embody the various aspects of this invention.

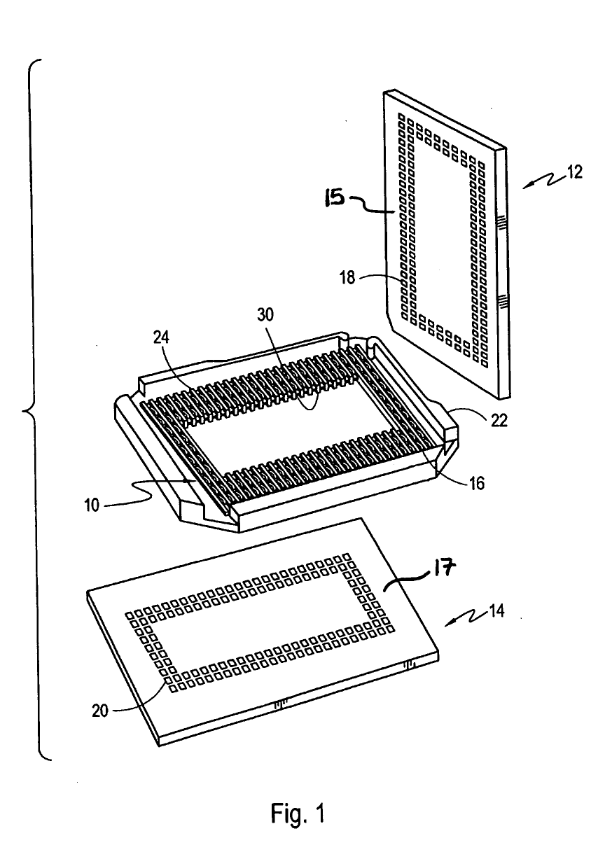

Generally, one embodiment of the present invention comprises an interconnect device that includes solder balls formed thereon. FIG. 1 illustrates one of various embodiments of an electrical connector 10 in accordance with the present invention. A first component 12 and a second component 14 are also shown in FIG. 1. As provided herein, the electrical connector 10 has a first side 24 and a second side 30. The first side 24 of the electrical connector 10 electrically connects to the first component 12 and the second side 30 of the electrical connector 10 electrically connects to the second component 14. Thus, the electrical connector 10 electrically connects the first component 12 to the second component 14. The electrical connectors 10, 60, 80, 110 disclosed herein and discussed in detail below also may be referred to as a “microprocessor connector,” a “socket,” an “interposer,” a “land grid array (LGA) socket,” and the like.

As shown, the electrical connector 10 includes a plurality of spaced apart electrical conductors 16. Similarly, the first component 12 includes a plurality of spaced apart contact pads 18 on a first side 15 thereof and the second component 14 includes a plurality of spaced apart conductive contact pads 20 on a first side 17 thereof. The contact pads 18, 20 can be lands or pads of various shapes and sizes. In the illustrated embodiment, each contact pad 18, 20 is a land and is a rectangular shaped flat surface. The plurality of contact pads 18, 20 or lands constitute a “land grid array.” Alternatively, the contact pads 18, 20 on the components 12, 14 can be constructed as balls or lands. Also, as further described below and for the purposes of this description, the conductors 16 exposed on the first side 24 of the electrical connector 10 are compression connected to the contact pads 18 on the first component while the conductors 16 exposed on the second side 30 of the electrical connector 10 are soldered to the contacts 20 on the second component. Those skilled in the art will appreciate, however, that the electrical connector 10 may be implemented such that both sides may be soldered connected to the first and second components 12, 14, without departing from the scope of the present invention.

As shown in FIG. 1, each electrical conductor 16 in the electrical connector 10 establishes an individual electrical circuit between a first contact pad 18 on the first component 12 and a corresponding second contact pad 20 on the second component 14. The electrical connector 10 also includes a frame 22 to isolate each electrical conductor 16 from the remaining electrical conductors 16. The shape, size, and design of the frame 22 can be varied to be compatible with a particular first component 12 and a particular second component 14. The first component 12 and the second component 14 illustrated in FIG. 1 are provided merely to facilitate this discussion.

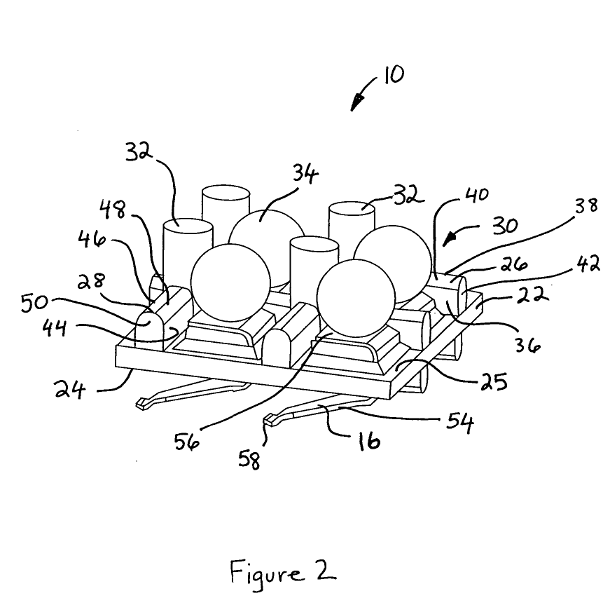

FIG. 2 is an enlarged perspective view of a portion of the electrical connector 10 with the second side 30 of the connector turned up. As discussed before, the second side 30 is provided to make an electrical connection with the contacts 20 located on the first side 17 of the component 14. The electrical connector 10 includes a plurality of electrical conductors 16. Each electrical conductor 16 is partially embedded in the molded frame 22. The molded frame 22 may be made from a rigid, substantially dielectric, non-conducting material, such as a thermoplastic, or may be formed of other suitable substantially dielectric, non-conducting engineering material.

The frame 22 is formed with a first side 24 opposed to the second side 30. The first side 24 is for contact with the first component 12 (shown in FIG. 1), while the second side 30 is for solder contact with the second component 14 (also shown in FIG. 1). The second side 30 of the frame includes pluralities of substantially coplanar first surfaces 26, which provide strength and minimize warping of the electrical connector 10 relative to the second component 14. The second side 30 also is formed with a plurality of coplanar second surfaces 28 which are positioned transversely from the plurality of coplanar first surfaces 26. Alone or in combination, the first and second surfaces 26, 28 form reinforcing strengthening ribs to minimize any warping of the electrical connector 10, and/or the components 12, 14 due to, for example, mismatches in thermal expansion or contraction between them.

The second side 30 of the frame 22 also includes a plurality of substantially coplanar solder collapsed control posts 32. The posts 32 extend outwardly from the second side 30 of the frame 22 and are substantially perpendicular to the base surface 25 of the frame 22. The posts 32 include a plurality of solder balls 34 formed therebetween. The posts 32 ensure the coplanarity of the electrical connector 10 with the second component 14. The posts are designed so that their feet are tapered and align the solders balls 34 in their position. When the electrical conductor 10 is reflow soldered to the second component 14, the electrical conductor 10 moves towards the second component 14 and the posts 32 make physical contact with the first side 17 of the second component 14. The solder collapsed control posts 32 can then distribute the force needed to compress the electrical conductors 16.

In one embodiment of the present invention, each one of the first surfaces 26 forming the strengthening ribs is formed with a first wall 36, a second wall 38, and a top 40. In one embodiment of the present invention, the walls 36, 38 of each first surface 26 are substantially flat while the top 40 of each first surface 26 is substantially curved. Nevertheless, the walls 36, 38, and the top 40 may be formed substantially flat and/or curved without departing from the scope of the present invention. For each first surface 26, the first and second walls 36, 38 extend from a front surface 42 to one of the plurality of the posts 32. Further, each one of the first and second walls 36, 38 is substantially perpendicular to a base surface 25 of the frame 22. Consequently, the top 40 of each first surface 26 is substantially parallel to the base surface 25.

Similarly, each one of the second surfaces 28 forming the strengthening ribs is formed with a first wall 44, a second wall 46, and a top 48. In one embodiment of the present invention, the walls 44, 46 of each one of the second surfaces 28 is substantially flat while the top 48 of each second surface 28 is substantially curved. Nevertheless, the walls 44, 46, and the top 48 may be formed substantially flat and/or curved without departing from the scope of the present invention. For each second surface 28, the first and second walls 44, 46 extend from a front surface 50 to one of the plurality of the posts 32. Further, each first and second wall 44, 46 are substantially perpendicular to the base surface 25. Consequently, the top 48 of each second surface 28 also is substantially parallel to the base surface 25.

The electrical connector 10 also includes a plurality of electrical conductors 16 molded in place within the frame 22. As shown, each electrical conductor 16 includes electrically continuous first and second portions 54, 56. The first portion 54 extends outwardly from the first side 24 of the frame 22 and terminates in a tip 58, designed to make a direct compression electrical contact with the contact pad 18 of the first component 12. The second portion 56 of the electrical conductor 16 extends through the frame 22 to the second side 30 of the frame 22 and provides a conductive land or conductive pad for receiving the solder ball 34. The electrical conductor 16 is shown stamped, shaped, preformed, and molded in place within the frame 22. In one embodiment of the present invention the electrical conductor 16 may be formed of an electrically conductive metal spring material, such as BeCu 172. In one embodiment, the electrical conductors 16 are stamped or formed from strips of electrically conductive metal spring material that are approximately 0.001 to 0.003 inches in thickness. Further, portions of the electrical conductor 16, or the entire electrical conductor 16, may be completely or selectively gold-plated on one side to a thickness of between 3 and 50 micro-inches to enhance the conductivity of the conductor 16. The solder mask is deposited on the top of the conductive land or conductive pad to define the footprint for the solder ball 34.

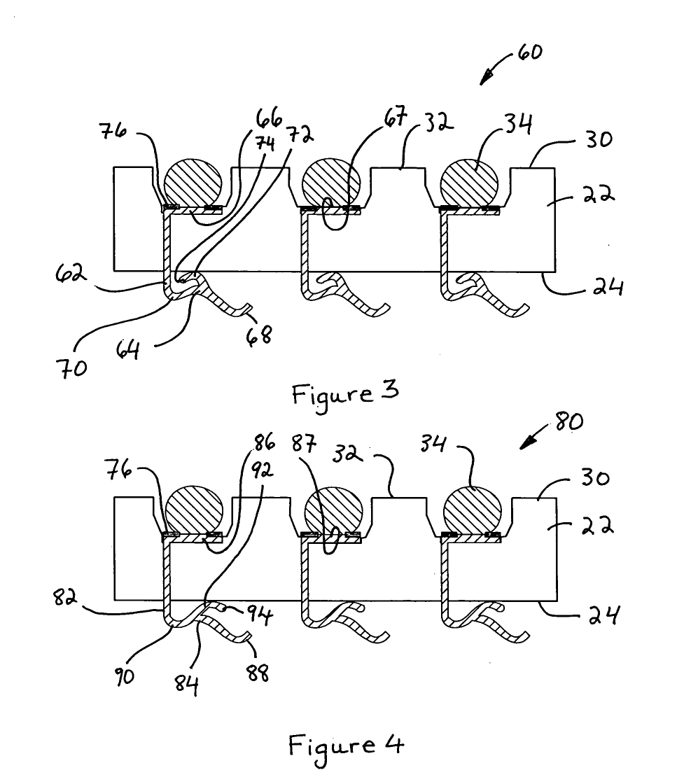

FIG. 3 illustrates one embodiment of an electrical connector 60 that includes a plurality of electrical conductors 62 molded in place within the frame 22. Each electrical conductor 62 includes electrically continuous first and second portions 64, 66. The first portion 64 extends outwardly from the first side 24 and terminates in a first tip 68, which makes a direct compression electrical contact with the contact pad 18 of the first component 12. The second portion 66 of the electrical conductor 62 extends through the frame 22 from the first side 24 to the second side 30 and provides an electrically conductive land 67 for receiving the solder ball 34 thereon. The second portion 66 of the electrical conductor 62 also includes solder mask 76 deposited thereon. The solder mask 76 may be deposited by screen printing, and stencil printing, for example. In the illustrated embodiment, the solder mask 76 is deposited using a stencil printing technique. The solder mask 76 controls the footprint of the solder ball 32 when it is formed. The molded frame 22 also includes the solder collapsed control posts 32 to align the solder balls 34 into their respective positions as they are formed on the conductive land 67. The solder collapsed control posts 32 ensure the coplanarity of the electrical connector 60 to the substrate, such as the second component 14, and correctly align the solder balls 34 to their position so that they coincide with the conductive lands, such as the contact pads 20 on the first side of the second component 14, for example.

The electrical conductor 62 is shown stamped, shaped, preformed, and molded in place in the frame 22. In one embodiment of the present invention, the electrical conductor 62 may be made from an electrically conductive metal spring material, such as BeCu 172. In the preferred embodiment, the electrical conductors 62 are stamped or formed from strips that are approximately 0.001 to 0.003 inches in thickness. Further, portions of the electrical conductor 62, or the entire electrical conductor 62, may be completely or selectively gold-plated on one side to a thickness of between 3 and 50 micro-inches to enhance the conductivity of the conductor 62.

The electrical conductor 62 also includes first and second spring force elements 70, 72. The first and second spring force elements 70, 72 provide the electrical conductor 62 with a resilient property when compressed after receiving the contact pad 18 of the first component 12. In one embodiment of the present invention the secondary spring force element 72 comprises a generally arcuate shaped member having a second tip 74 that extends in a direction substantially opposite to the first tip 68.

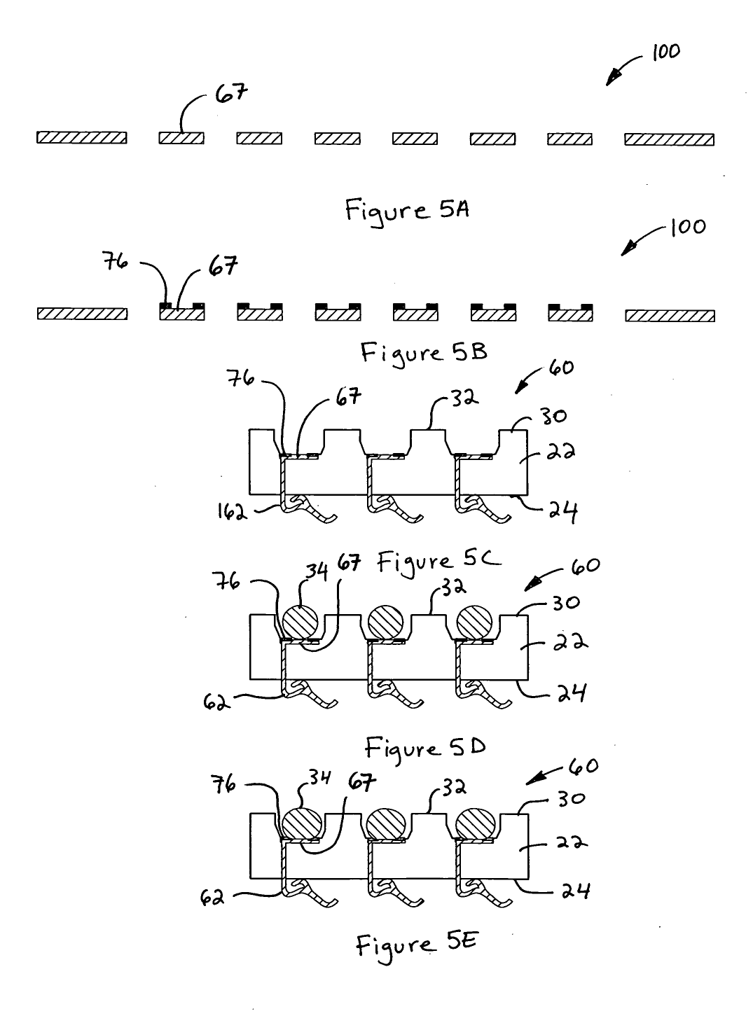

FIG. 4 illustrates another embodiment of an electrical connector 80 that includes a plurality of electrical conductors 82 molded in place in the frame 22. Each electrical conductor 82 includes electrically continuous first and second portions 84, 86. The first portion 84 extends outwardly from the first side 24 of the frame 22 and terminates in a first tip 88, which makes direct compression electrical contact with the contact pad 18 of the first component 12. The second portion 86 of the electrical conductor 82 extends through the frame 22 from the first side 24 to the second side 30 and provides an electrically conductive land 87 for receiving solder paste thereon for forming the solder ball 34 thereon. As discussed with respect to FIG. 3, the second portion 86 of the electrical conductor 82 also includes solder mask 76 deposited thereon and the solder collapsed control posts 32.

The electrical conductor 82 also includes first and second spring force elements 90, 92. The first and second spring force elements 90, 92 provide the electrical conductor 82 with a resilient property when compressed after receiving the contact pad 18 of the first component 12. In one embodiment of the present invention the secondary spring force element 92 comprises a generally arcuate shaped member having a second tip 94 that extends substantially in the same direction as the first tip 88.

FIGS. 5A-E illustrate a process sequence for attaching solder balls 34 on the electrical connector 60 according to one embodiment of the present invention. The process illustrate the sequence of depositing a solder mask 76 on the electrically conductive pad 67. The solder balls 34 allow the electrical conductors 16, 62, 82 of the electrical connectors 10, 60, 80, respectively, to be soldered to contact pads 20 of the second component 14. The process illustrated in FIGS. 5A-E may be applied to attach the solder balls 34 on any one of the previously described surface mountable electrical connectors 10, 80, however, for brevity, the process will be described only with respect to the electrical connector 60.

FIG. 5A illustrates a stamped, plated, and heat treated contact lead-frame 100 comprising a plurality of conductive pads 67 for receiving the solder mask 76. The wet solder mask material may be cured with either Ultra Violet (UV) light or heat. FIG. 5B illustrates the lead-frame 100 with the solder mask 76 material deposited on the conductive pad 67. FIG. 5C illustrates the process step after the individual conductive pads 162 comprising the solder mask 76 are removed from the lead frame 100 and are inserted into the molded frame 22. The electrical conductors 62 are placed between the plurality of substantially coplanar solder control posts 32 on the second side 30 of the electrical connector 60.

FIG. 5D illustrates the electrical connector 60 with the solder balls 34 attached on the surface of the conductive pads 162 within the space defined by the solder mask 76. As shown in FIG. 5D, the solder balls 34 have not yet been reflowed (melted), but rather are shown just after deposition onto the conductive pads 162. FIG. 5E illustrates the electrical connector 60 with the solder balls 34 after the reflow process. Once the solder balls 34 are reflowed, the solder paste wets the surface area on the contact pad 162 defined by the solder mask 76.

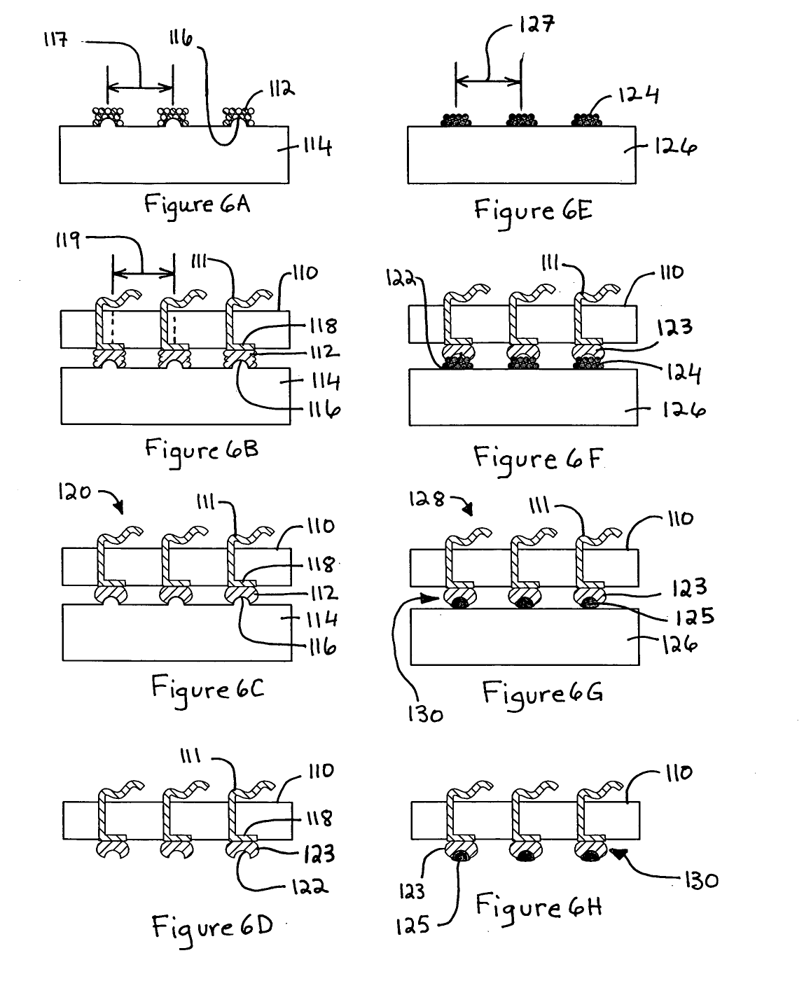

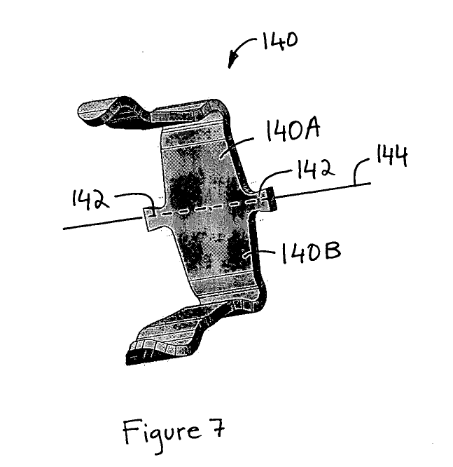

Solder balls 34 can be attached to the contact pad 162 by solder reflow or formed by solder paste stenciled then reflowed on the surface area on the contact pad 162 with the footprint defined by the solder mask 76. FIGS. 6A-H illustrates a process sequence for forming a dual solder ball array type electrical connector 110 according to one embodiment of the present invention on any one of the electrical connectors 10, 60, 80 discussed above. For the sake of brevity, however, the process of forming the dual solder ball array type electrical connector 110 will be described with respect to the electrical connector 110 shown in FIGS. 6B-H.

FIG. 6A illustrates the first step in the process. A first solder paste 112 having a first higher liquidus point (e.g., melting point) is deposited on a temporary glass substrate 114 having a plurality of convex dome shaped features, hereinafter referred to as bumps 116, forming an array on the substrate 114 that coincides with the desired orientation and position of the dual solder ball array to be formed on the electrical conductors 111 of the electrical connector 110 (see FIGS. 6A-H). Those skilled in the art will appreciate that the first solder paste 112 may be deposited on the temporary glass substrate 114 using a variety of well known techniques such as by screen printing, or stencil printing techniques. As shown in FIG. 6A, the first solder paste 112 array is stenciled directly on the bumps 116. The bumps 116 are arranged such that the spacing 117 between them, and hence between the first solder paste 112, aligns and coincides with the spacing 119 between the electrical conductors 111 forming the connector 110.

FIG. 6B illustrates the second step in the sequence. The temporary glass substrate 114 comprising the first solder paste 112 array is aligned and oriented with the conductive pads 118 portions of the electrical conductors 111 of the connector 110. Once the electrical connector 110 and the temporary glass substrate 114 are aligned and oriented such that the electrical conductive pads 118 coincide with the array of bumps 116, the electrical conductive pads 118 are placed in communication with the first solder paste 112.

As shown in FIG. 6C, the first solder paste 112 is then melted or reflowed by applying heat to the electrical connector/temporary glass substrate assembly 120 until the temperature of the first solder paste 112 reaches or exceeds the first liquidus point and reflows (melts), wetting the electrically conductive pads 118. When the heat is applied to the first solder paste 112 it forms into a ball shape due to its inherent surface tension when it is reflowed. Furthermore, upon heating, the first solder paste 112 wicks towards the conductive pads 118 and conforms around the glass bumps 116. The heat is then removed and the first solder paste 112 is allowed to cool to a temperature below the liquidus point to solidify. In one embodiment of the present invention the heating process described above may include a first step of initially preheating the entire assembly 120 comprising the temporary glass substrate 114, the components such as the electrical connector 110, the electrical conductors 111, and the first solder paste 112, for example, to a temperature below the liquidus point of the first solder paste 112. A second step includes further heating the entire assembly 120 using pulsed heat to raise the temperature up to or above the required liquidus point of the first solder paste 112, causing it to reflow. The first solder paste 112 is then allowed to cool to a temperature below the liquidus point, forming a ball-like structure conforming about the bumps 116 on the surface of the glass substrate 114.

FIG. 6D shows the electrical connector 110 after removing the temporary glass substrate 114 from the electrical connector 110 and after the first solder paste 112 has cooled and solidified. The connector 110 now includes a first solder ball 123 having a concave shaped feature, hereinafter referred to as a reservoir 122, which is the inverse form of the bump 116. The reservoir 122 in the first solder ball 123 is for receiving a second solder paste of lower melting temperature 124 (see FIG. 6G).

FIG. 6E shows a second solder paste of lower melting temperature 124 deposited on a second temporary flat glass substrate 126 (e.g., with no bumps). The second solder paste 124 has a second liquidus point that is lower from the first liquidus point. As discussed above, the second solder paste 124 may be deposited using a variety of techniques. As shown in FIG. 6E, the second solder paste 124 is deposited by a stencil printing technique. The spacing 127 between the second solder paste 124 also is selected to coincide with the spacing 117 between the first solder balls 123 and accordingly with the spacing 119 between the electrical conductors 111 of the connector 110.

FIG. 6F shows the connector 110 having the first solder balls 123 formed with the reservoir 122 for receiving the second solder paste 124. The electrical connector 110 is aligned with the second temporary glass substrate 126 such that the first solder balls 123 coincide with the second solder paste 124 on the second temporary glass substrate 126. The first solder balls 123 are then placed in communication with the second solder paste 124.

As shown in FIG. 6G, the second solder paste 124 is melted or reflowed by applying heat to the electrical connector/temporary glass substrate assembly 128 until the second solder paste 124 temperature reaches or exceeds the second liquidus point and reflows, wetting and filling the reservoir 122 formed in the first solder ball 112. Those skilled in the art will appreciate that the second liquidus point is selected such that it is lower than the first liquidus point such that the first solder balls 123 do not melt during the reflow process for the second solder paste 124. As the temperature reaches or exceeds the second liquidus point, the second solder paste 124 reflows and wicks up into the reservoir 122 forming a second solder ball 125 within the first solder ball 123. As discussed above, in one embodiment of the present invention the heating process may include a first step of initially preheating the entire assembly 128 comprising the second temporary glass substrate 126, the components such as the electrical connector 110, the electrical conductors 111, and the second solder paste 124 to a first temperature, which is lower than the second liquidus point. A second step may include further heating the entire assembly 128 using pulsed heat to raise the temperature up to or beyond the second liquidus point to reflow the second solder paste 124. After the second solder paste 124 reflows, it is allowed to cool to a temperature below the second liquidus point to solidify, thus forming a dual solder ball 130 structure comprising the first solder ball 123, which reflows at the first liquidus point and the second solder ball 125, which reflows at the second liquidus point.

As shown in FIG. 6H, once the second solder ball 125 is formed, the second temporary glass substrate 126 is removed from the connector 110 leaving the dual solder ball 130 structure.

FIG. 7 illustrates an electrical conductor 140 comprising anti-pivot elements 142 in accordance with one embodiment of the present invention. As shown in FIG. 7, the electrical conductor 140 comprises two separate electrical conductors 140A, 140B that are formed by stamping or other process from one continuous electrically conductive metal spring material, such as BeCu 172. In one embodiment, the electrical conductors 140A, B are stamped or formed from strips that are approximately 0.001 to 0.003 inches in thickness. Further, portions of the electrical conductor 140, or the entire electrical conductor 140, may be completely or selectively gold-plated on one side to a thickness of between 3 and 50 micro-inches to enhance the conductivity of the conductor 140. Once the electrical conductor 140 is formed, it is cleaved along line 144 to form the two separate electrical conductors 140A, B for insert molding into the frame 22 (discussed above). The anti-pivot elements 142 help prevent uneven torque during assembly and assist in inserting and removing the electrical contacts 140A, B in the molding process when the electrical contacts 140A, B are molded into the frame 22. The anti pivot elements 142 assist in preventing the electrical contacts 140A, B from loosening within the frame 22 over time. The anti pivot elements 142 also provide an anchoring function that prevent the electrical contacts 140A, B from loosening over time. Any of the electrical contacts 16, 62, 82, 111 discussed above may be formed comprising the anti-pivot elements 142 described herein. The present invention is intended to cover all such embodiments and combination thereof.

Although the present invention has been described with regard to certain embodiments, those of ordinary skill in the art will recognize that many modifications and variations of the present invention may be implemented. The foregoing description and the following claims are intended to cover all such modifications and variations. Furthermore, the components and processes disclosed are illustrative, but are not exhaustive. Other components and processes also may be used to make systems and methods embodying the present invention.

Furthermore, in the claims appended hereto any element expressed as a means for performing a specified function is to encompass any way of performing that function including, for example, a combination of elements that perform that function. Furthermore the invention as defined by such means-plus-function claims resides in the fact that the functionalities provided by the various recited means are combined and brought together in the manner that the claims called for. Therefore, any means that can provide such functionalities may be considered equivalents to the means shown herein.

1. A connector, comprising:
a frame having a first side and a second side;
a conductor including electrically continuous first and second portions, the first portion extending outwardly from the first side of the frame and terminating in a tip, the second portion extending through the second side of the frame and terminating in a land; and
a solder ball formed on the land.

2. The connector of claim 1, further comprising a plurality of substantially coplanar first surfaces formed on the second side of the frame, wherein the first surfaces are for strengthening the frame and minimizing warping of the frame.

3. The connector of claim 2, further comprising a plurality of substantially coplanar second surfaces formed on the second side of the frame, wherein the second surfaces are positioned transversely from the first surfaces, wherein the second surfaces are for strengthening the frame and minimizing warping of the frame.

4. The connector of claim 1, further comprising a solder collapsed control post formed on the second side of the frame, wherein the post extends perpendicularly outwardly from the second side of the frame.

5. The connector of claim 1, wherein the conductor is made of a solid metallic material.

6. The connector of claim 1, wherein the first portion of the conductor extending outwardly from the first side of the frame is shaped for compression connection with the first component.

7. The connector of claim 6, wherein the second portion of the conductor including the solder ball is shaped for solder connection with the second component.

8. The connector of claim 1, wherein the first portion of the conductor extending outwardly from the first side of the frame is shaped for compression connection with the second component.

9. The connector of claim 8, wherein the second portion of the conductor including the solder ball is shaped for solder connection with the first component.

10. The connector of claim 1, wherein the land of the second portion of the conductor further comprises a solder mask deposited thereon defining a region for receiving the solder ball.

11. The connector of claim 1, wherein the first portion of the conductor further comprises a first spring element extending in a first direction.

12. The connector of claim 11, wherein the first portion of the conductor further comprises a second spring element having a generally arcuate shaped member having a second tip, wherein the second tip extends in the same direction as the tip of the first spring element.

13. The connector of claim 11, wherein the first portion of the conductor further comprises a second spring element having a generally arcuate shaped member having a second tip, wherein the second tip extends in the opposite direction as the tip of the first spring element.

14. The connector of claim 1, wherein the solder ball comprises solder having different liquidus points.

15. The connector of claim 1, wherein the lead frame is comprised of a dielectric material.

16. The connector of claim 1, wherein the conductor further comprises an anti-pivoting element.

17. A method of forming a connector comprising a solder ball, the method comprising:
depositing solder mask on a conductive pad of a conductor, the solder mask defining an area for receiving solder paste;
depositing solder paste in the area defined by the solder mask; and
forming a solder ball by reflowing the solder paste.

18. The method of claim 17, further comprising providing a lead frame including the conductor.

19. The method of claim 17, further comprising providing a conductor comprising a first spring element.

20. The method of claim 19, further comprising providing a conductor comprising a second spring element.

21. A method of forming a connector comprising a solder ball, the method comprising:
depositing a first solder paste on a first substrate comprising a convex region;
introducing a conductive pad of a conductor in communication with the first solder paste;
reflowing the first solder paste to form a first solder ball defining a reservoir;
depositing a second solder paste on a second substrate;
introducing the reservoir portion of the first solder ball in communication with the second solder paste; and
reflowing the second solder paste to form a second solder ball within the reservoir portion of the first solder ball.

22. The method of claim 21, wherein the temporary glass substrate has a plurality of convex dome shaped features to be used in the manufacturing processes to form the reservoir for the second solder ball.

23. The method of claim 21, wherein depositing the first solder paste further comprises depositing a first solder paste having a first liquidus point; and wherein depositing the second solder paste further comprises depositing a second solder paste having a second liquidus point.

24. The method of claim 23, wherein reflowing the first solder paste further comprises reflowing the first solder paste at a temperature equal to at least the first liquidus point and reflowing the second solder paste at a temperature equal to at least the second liquidus point.

25. The method of claim 24, wherein the first liquidus point is greater than the second liquidus point.

26. The method of claim 21, wherein reflowing the first solder paste further comprises:
preheating to a temperature below a liquidus point of the first solder paste; and
pulse heating to a temperature equal to at least the liquidus temperature of the first solder paste.

27. The method of claim 26, wherein reflowing the second solder paste further comprises:
preheating to a temperature below a liquidus point of the second solder paste; and
pulse heating to a temperature equal to at least the liquidus temperature of the second solder paste;
wherein the liquidus temperature of the first solder paste is greater than the liquidus temperature of the second solder paste.

28. The method of claim 21, wherein introducing a conductive pad of a conductor in communication with the first solder paste further comprises introducing any one of a conductive pad consisting of an electrical conductor, an electrical conductor having a first spring element, an electrical conductor having a second spring element, and an electrical conductor having anti-pivoting elements.

29. The method of claim 21, further comprising cooling the first solder ball.

30. The method of claim 21, further comprising cooling the second solder ball.

31. An interconnect system, comprising:
a first component including a first contact pad thereon;
a second component including a second contact pad thereon; and
a connector comprising:
a frame having a first side and a second side;
a conductor including electrically continuous first and second portions, the first portion extending outwardly from the first side of the frame and terminating in a tip in electrical communication with the first contact pad, the second portion extending through the second side of the frame and terminating in a land in electrical communication with the second contact pad; and
a solder ball formed on the land.

32. The system of claim 31, further comprising a plurality of substantially coplanar first surfaces formed on the second side of the frame, wherein the first surfaces are for strengthening the frame and minimizing warping of the frame.

33. The system of claim 32, further comprising a plurality of substantially coplanar second surfaces formed on the second side of the frame; wherein the second surfaces are positioned transversely from the first surfaces; and wherein the second surfaces are for strengthening the frame and minimizing warping of the frame.

34. The system of claim 31, further comprising a solder collapsed control post formed on the second side of the frame; wherein the post extends perpendicularly outwardly from the second side of the frame; and wherein the post is in communication with the second component.

35. The system of claim 31, wherein the conductor is made of a solid metallic material.

36. The system of claim 31, wherein the first portion of the conductor extending outwardly from the first side of the frame is in compression connection with the first component.

37. The system of claim 36, wherein the second portion of the conductor including the solder ball is in solder connection with the second component.

38. The system of claim 31, wherein the first portion of the conductor extending outwardly from the first side of the frame is in compression connection with the second component.

39. The system of claim 38, wherein the second portion of the conductor including the solder ball is in solder connection with the first component.

40. The system of claim 31, wherein the land of the second portion of the conductor further comprises solder mask deposited thereon defining a region for receiving the solder ball.

41. The system of claim 31, wherein the first portion of the conductor further comprises a first spring element extending in a first direction.

42. The system of claim 41, wherein the first portion of the conductor further comprises a second spring element having a generally arcuate shaped member having a second tip, wherein the second tip extends in the same direction as the tip of the first spring element.

43. The system of claim 41, wherein the first portion of the conductor further comprises a second spring element having a generally arcuate shaped member having a second tip, wherein the second tip extends in the opposite direction as the tip of the first spring element.

44. The system of claim 31, wherein the solder ball comprises solder having different liquidus points.

45. The system of claim 31, wherein the frame is comprised of a dielectric material.

46. The system of claim 31, wherein the conductor further comprises an anti-pivoting element.
